(19) United States
(12) Patent Application Publication
(10) Pub. No.: US 2010/0155863 A1
(43) Pub. Date: Jun. 24, 2010

(54) METHOD FOR MANUFACTURING A MICROELECTRONIC PACKAGE COMPRISING A SILICON MEMS MICROPHONE

(75) Inventor: Johannes Wilhelmus Weekamp, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/063,117

(22) PCT Filed: Aug. 4, 2006
(86) PCT No.: PCT/IB06/52698

§ 371 Date: Feb. 7, 2008

(30) Foreign Application Priority Data
Aug. 11, 2005 (EP) 05107401.1

(51) Int. Cl. H01L 29/84; H01L 21/02; H04R 25/00

(52) U.S. Cl. 257/416; 438/51; 381/175; 257/E29.324; 257/E21.002

(57) ABSTRACT

A method for manufacturing a microelectronic package comprising a silicon MEMS microphone comprises the following steps: providing a basic panel (100) having several rows of interconnected substrates (90), wherein the substrates (90) are provided with electrically conductive connection pads (31), electrically conductive tracks (33), and a grid (40) comprising tiny holes (41); arranging an IC chip (50), a silicon MEMS microphone (60) and a ring-shaped element (95) on the substrates (90), wherein the ring-shaped element (95) is arranged around the microphone (60); and folding the substrates (90) in three, wherein an open side of the ring-shaped element (95) is closed. The IC chip (50) and the microphone (60) are safely accommodated in the package (5) that is obtained in this way. The connection pads (31) allow for easy connection of the package (5) to another device, while 32 electrical connections to the IC chip (50) are also easily realized through these connection pads (31). An electrical connection of the microphone (60) to the IC chip (50) is realized through the electrically conductive tracks (33).

The present invention relates to a method of manufacturing a microelectronic package comprising an acoustical transducer, which is an element capable of receiving sound and generating an electrical signal on the basis of the sound. In particular, the present invention relates to a method of manufacturing a microelectronic package comprising a silicon MEMS microphone. Furthermore, the present invention relates to a package comprising an acoustical transducer such as a silicon MEMS microphone.

A silicon MEMS microphone is known in practice. For sake of completeness, it is noted that MEMS stands for Micro ElectroMechanical System. In general, a silicon MEMS microphone comprises a silicon substrate forming a frame of the microphone. In the substrate, a hole is arranged, which is tapered in many cases. Furthermore, the microphone comprises a flexible membrane and a stiff backplate, wherein the flexible membrane is in close proximity of the backplate. During operation of the microphone, an electrical charge is applied to the backplate, wherein the whole of the backplate and the flexible membrane acts as a capacitor. As the flexible membrane deforms under the influence of sound, an electrical signal representing the sound is obtained on the basis of resulting variations of the capacity of the capacitor.

As the silicon MEMS microphone has dimensions in the micrometer range, numerous applications of the microphone are possible, including applications in mobile phones.

For the purpose of practical applications of the silicon MEMS microphone, it is important that the microphone is arranged inside a package. Examples of such a package are known from US 2005/0018864. In one embodiment, the package comprises a silicon substrate, an air cavity arranged in the substrate, and a silicon cover which is placed on top of the substrate. In the space enclosed by the substrate and the cover, a silicon MEMS microphone and an amplifier are disposed, wherein the microphone is positioned above the air cavity. During operation of the microphone, the air cavity serves as a pressure reference for the microphone. An upper side of the microphone, i.e. a side where the membrane is located, is connected to the substrate. The cover comprises an aperture which may contain a metal insert, and which is arranged at a position above the microphone. The aperture is adapted for allowing sound waves to reach the microphone. A bottom side of the package may be connected to a printed circuit board via a solder reflow process.

It is an objective of the present invention to provide another package for an acoustical transducer such as a silicon MEMS microphone, which is robust, cheaper than the packages known thus far, as small as possible, and easy to manufacture, while offering an environment in which it is possible for the acoustical transducer to function properly, including an acoustical back chamber. The objective is achieved by means of a new method of manufacturing a microelectronic package comprising an acoustical transducer such as a silicon MEMS microphone, which comprises the following steps:

providing a basic structure having three portions, namely a first package portion having electrically conductive connection pads for connection of the package to another electrical device, a second package portion having a space in which the acoustical transducer is accommodated, and an intermediate package portion which is arranged between the first package portion and the second package portion;

folding the basic structure, wherein a package is formed in which the first package portion and the second package portion are positioned on top of each other, and in which the electrically conductive connection pads of the first package portion are positioned at an outside of the package, while the acoustical transducer is positioned inside the package; and

fixing the first package portion and the second package portion with respect to each other.

In short, the present invention involves packing an acoustical transducer in a folded package. It is noted that in general, methods for forming a microelectronic package, which include a step of folding a substrate, are known, for example from WO 2004/017399. However, the present invention is not to be regarded as being nothing more than an application of known techniques for forming folded packages in the field of MEMS microphones. On the contrary, packing an acoustical transducer such as a silicon MEMS microphone in a package by means of the method according to the present invention offers specific advantages and leads to surprising results.

An important aspect of the present invention is that a very simple solution for connecting the acoustical transducer to electrically conductive connection pads at the outside of the package is provided. In particular, it is possible to provide a basic structure having such pads on the first package portion, and having electrically conductive tracks extending from the pads on the first package portion to the second package portion, via the intermediate package portion. In the second package portion, the acoustical transducer is connected to ends of the electrically conductive tracks.

Likewise, in case the package is also equipped with another microelectronic element such as an IC chip, it is very easy to realize a connection of this element to electrically conductive connection pads at the outside of the package. In case the microelectronic element is arranged on the second package portion, the element is connected to the acoustical transducer through electrically conductive tracks provided on the second package portion, and the element is connected to the electrically conductive connection pads on the first package portion through electrically conductive tracks extending from the pads on the first package portion to the second package portion, via the intermediate package portion. In case the microelectronic element is arranged on the first package portion, the element is directly connected to the electrically conductive connection pads, while the acoustical transducer is connected to the element through electrically conductive tracks extending from the second package portion to the first package portion, via the intermediate package portion.

In the folded package which is obtained by carrying out the method according to the present invention, the first package portion constitutes a portion through which the package may be connected to another electrical device such as a printed circuit board, while the acoustical transducer is present in the second package portion. In case the acoustical transducer comprises a silicon MEMS microphone, contacts of the microphone are usually present at an upper side of the microphone, i.e. the side where the membrane of the microphone is located. Therefore, the microphone is preferably attached to the second package portion at its upper side. In the folded package according to the present invention, this is just the case. In the basic structure, the microphone is attached to the second package portion upside down. Once the basic structure has been folded and fixed in the folded condition, and the obtained package is placed on top of another electrical device, wherein the package is connected to the electrical device through the electrically conductive connection pads at the first package portion, the microphone is in an upright position, hanging from its connections to the second package portion, as it were. An additional advantage is that in this orientation of the microphone, it is possible for the hole in the silicon frame of the microphone to be in open communication with an inside space of the package, wherein both the hole and the inside space may function as an acoustical back chamber of the microphone. As a consequence, the inside space may be as small as possible, and the package may be as small as possible.

The proposed method of manufacturing a microelectronic package comprising an acoustical transducer is relatively simple. Before the final steps of folding the basic structure and fixing the first package portion and the second package portion with respect to each other are carried out, the basic structure may be processed from all sides. Also, the basic structure may initially be part of a larger basic panel, wherein the basic structure is completely separated from the basic panel after the steps of folding the basic structure and fixing the first package portion and the second package portion with respect to each other have been carried out. In this way, it is very well possible to manufacture a collection of packages at one time. Furthermore, handling a relatively large basic panel is easier than handling a single basic structure.

On the basis of the fact that according to the present invention, the package is manufactured in a simple manner, the package may be relatively cheap. Moreover, the package may even be cheaper as a result of the fact that there is no need for applying expensive materials such as silicon in the package.

Advantageously, the step of providing the basic structure of the package comprises the steps of providing a foldable substrate; arranging the electrically conductive connection pads for connection of the package to another electrical device on a first portion of the substrate; and arranging the acoustical transducer on a second portion of the substrate; and the step of folding the basic structure comprises folding the substrate in three. The foldable substrate may comprise any suitable kind of nonconducting flexible material, for example a polyamide material, an acrylic material, or an epoxy material.

The second package portion comprises a space for accommodating the acoustical transducer. Within the scope of the present invention, the space may be created in any suitable manner. For example, the second package portion is provided with a layer having a cavity for receiving the acoustical transducer. Such layer may be molded by means of a mould tool having a projecting portion for forming the cavity in the layer. It is also possible that the second package portion is provided with a ring-shaped element enclosing a space for receiving the acoustical transducer, or with a cover having a space for accommodating the acoustical transducer, wherein the cover is placed over the acoustical transducer after the transducer has been put in place.

In case the method according to the present invention comprises the step of providing another microelectronic element and this element is arranged on the first package portion, the method may also comprise a step of providing the first package portion with a ring-shaped element enclosing a space for receiving the element. Within the scope of the present invention, a package having two ring-shaped elements may be manufactured, wherein the ring-shaped element of the second package portion encloses the acoustical transducer, and wherein the ring-shaped element of the first package portion encloses another microelectronic element. The ring-shaped elements may be of approximately the same size, and may be put on top of each another in the folded package, so that a very robust construction is obtained.

Preferably, the electronically conductive connection pads and the electronically conductive tracks of the package are arranged on the basic structure by arranging the connection pads and the tracks on a carrying surface of a sacrificial carrier; applying material of the basic structure to the carrying surface of the sacrificial carrier; and removing the sacrificial carrier. For example, the sacrificial carrier may comprise aluminum, and the pads and tracks may comprise copper, wherein the aluminum is removed by means of etching.

Advantageously, for the purpose of allowing sound waves to reach the acoustical transducer in the package, a collection of holes forming a grid is arranged in a portion of the second package portion. In principle, it is also possible to arrange one relatively large hole in the second package portion, but it is preferred to have a grid for preventing water, (dust) particles and/or light from entering the package, as this may be harmful to the acoustical transducer and any other microelectronic element.

A practical possibility of fixing the first package portion and the second package portion with respect to each other involves glueing together these package portions. However, within the scope of the present invention, other suitable fixing techniques may be applied.

The present invention also relates to a package, comprising:

an acoustical transducer such as a silicon MEMS microphone;

a first package portion having first electrically conductive connection pads for connection of the package to another electrical device;

a second package portion having a space in which the acoustical transducer is accommodated, wherein the package portions are positioned on top of each other; and

an intermediate sheet which is connected to both package portions, and which is arranged at an outside of the package.

In a preferred embodiment of the package according to the present invention, the intermediate sheet is a middle part of a substrate folded in three, which extends at an outside of the package, and which is part of both the first package portion and the second package portion.

In the package according to the present invention, at least one element which is arranged on the second package portion, and which may be the acoustical transducer or another microelectronic element, is connected to the electrically conductive connection pads of the first package portion through electrically conductive tracks extending from the element to the pads, at the outside of the package, over the intermediate sheet.

The present invention will now be explained in greater detail with reference to the Figures, in which similar parts are indicated by the same reference signs, and in which:

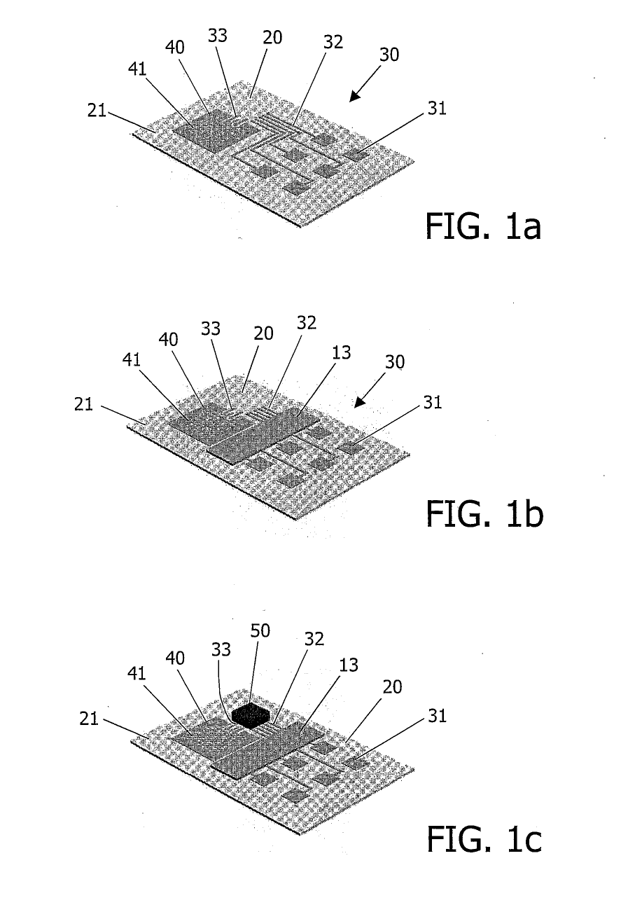

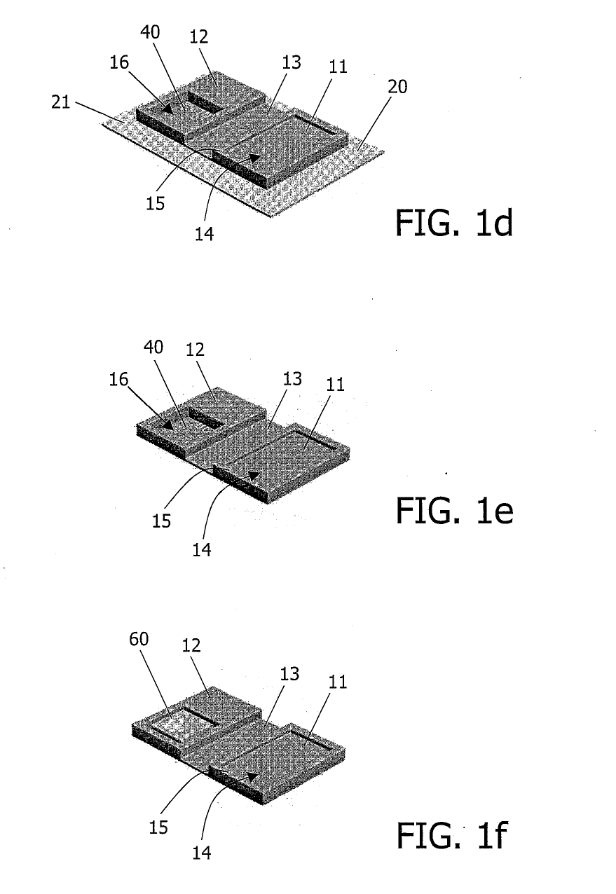

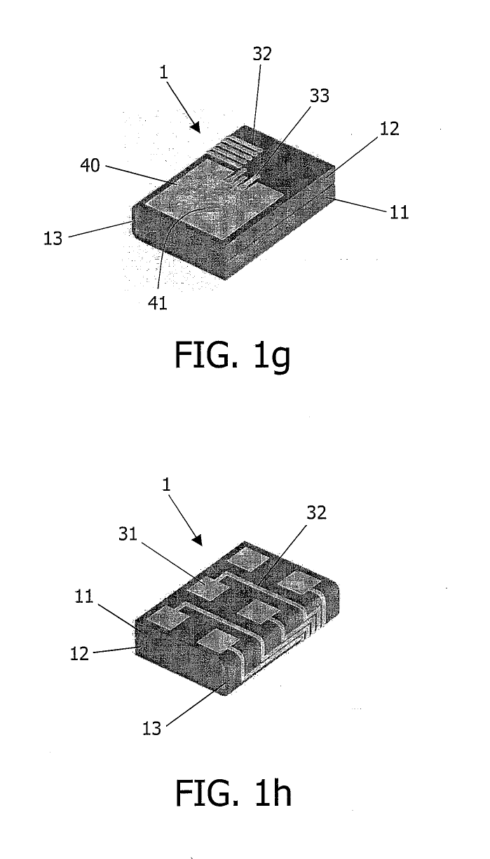

FIGS. 1a, 1b, 1c, 1d, 1e and 1f illustrate subsequent steps of a first preferred process of manufacturing a microelectronic package having a silicon MEMS microphone;

FIGS. 1g and 1h are different views of the package which is obtained as a result of the first preferred manufacturing process;

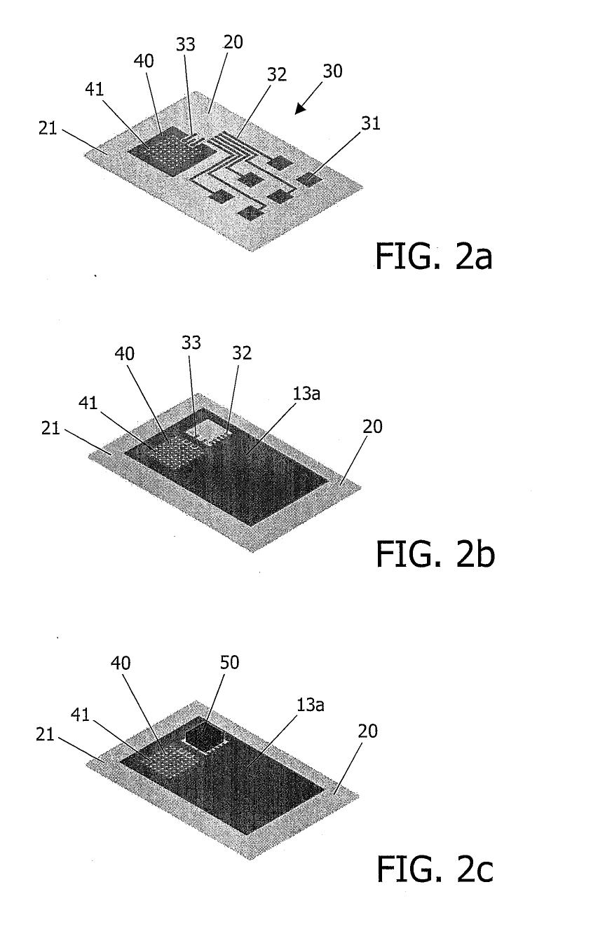

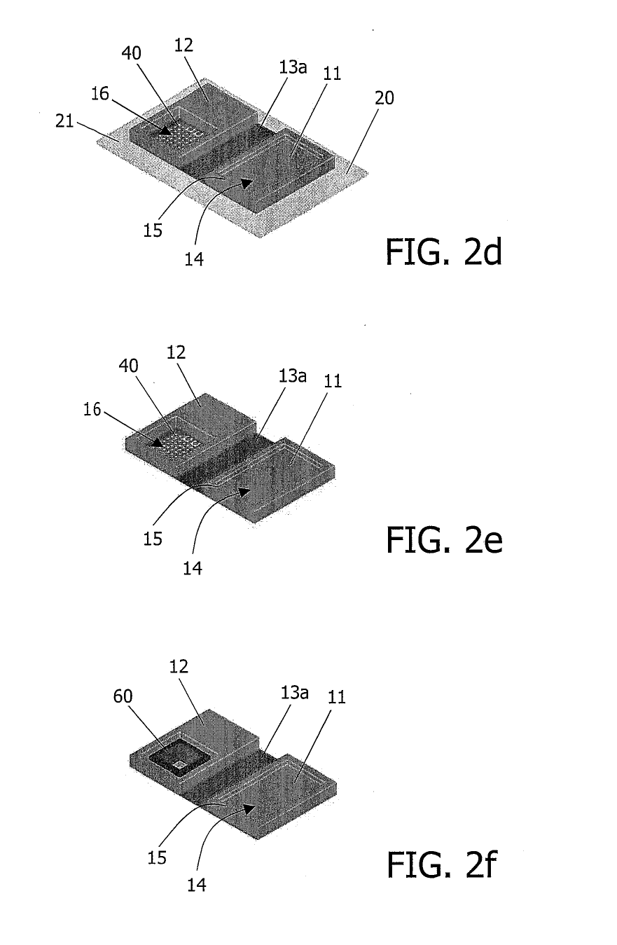

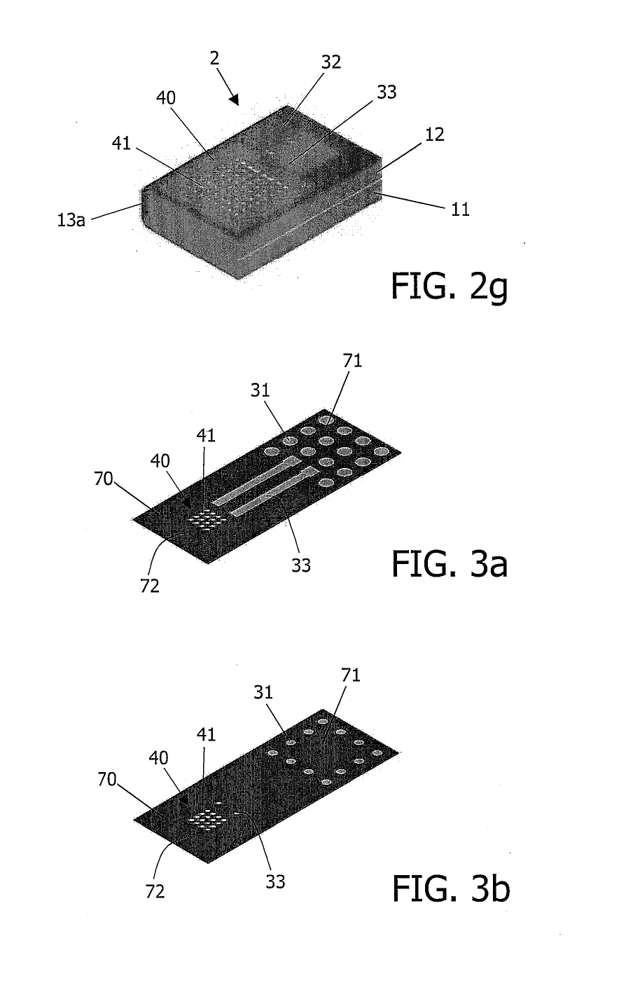

FIGS. 2a, 2b, 2c, 2d, 2e and 2f illustrate subsequent steps of a second preferred process of manufacturing a microelectronic package having a silicon MEMS microphone;

FIG. 2g is a view of the package which is obtained as a result of the second preferred manufacturing process;

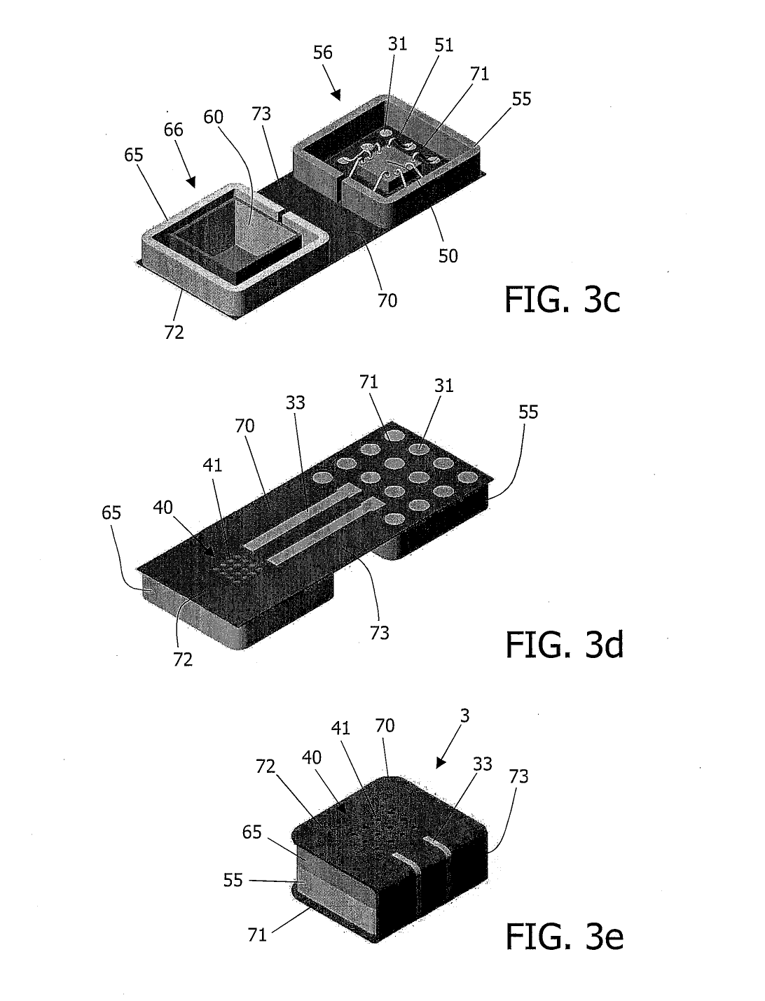

FIGS. 3a and 3b are different views of a substrate which is used in a third preferred process of manufacturing a microelectronic package having a silicon MEMS microphone;

FIGS. 3c and 3d are different views of a whole of the substrate as shown in FIGS. 3a and 3b and a number of elements arranged on the substrate;

FIG. 3e is a view of the package which is obtained as a result of the third preferred manufacturing process;

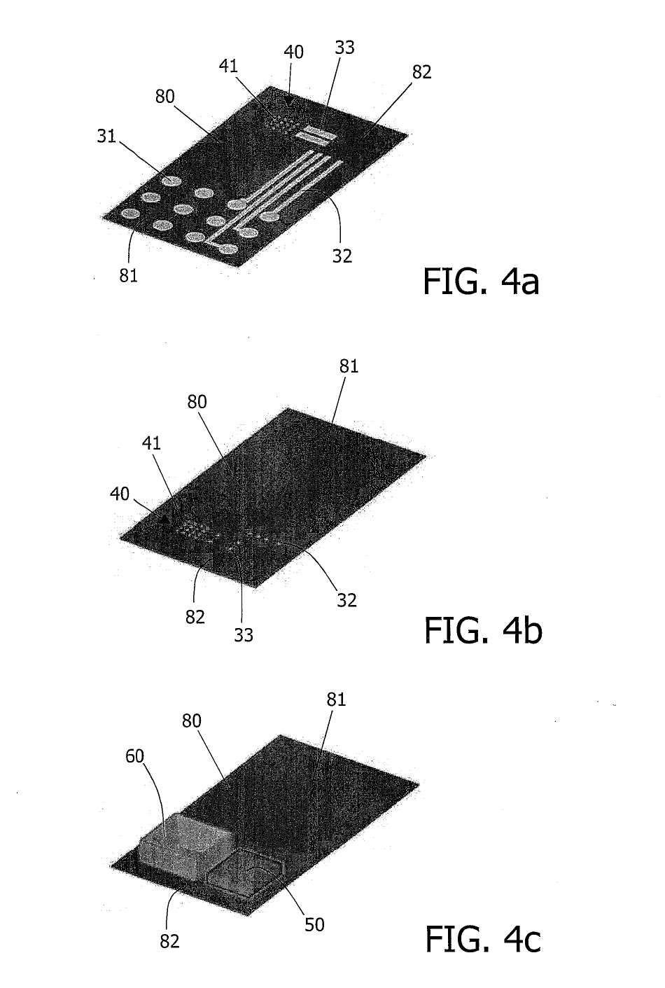

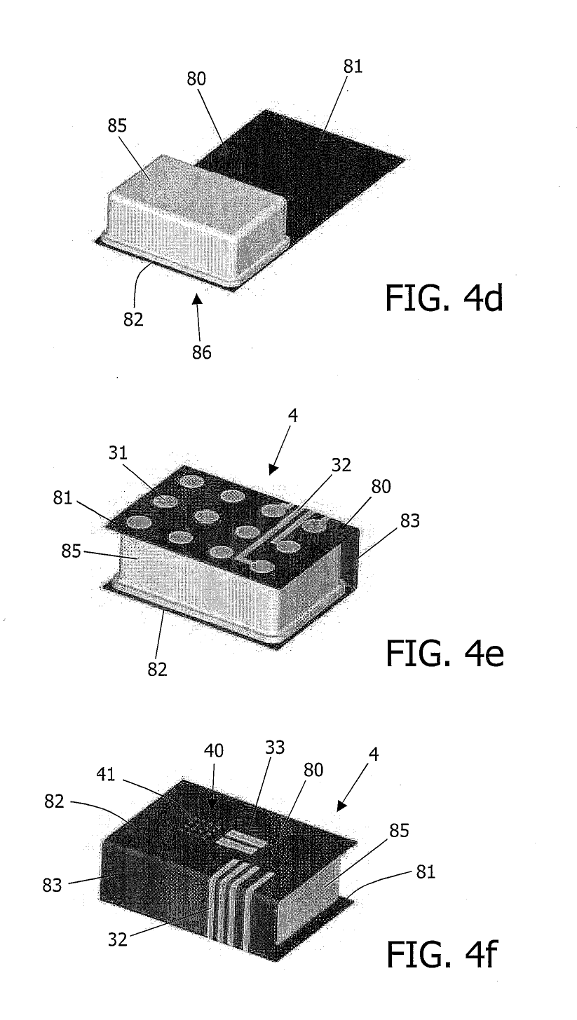

FIGS. 4a and 4b are different views of a substrate which is used in a fourth preferred process of manufacturing a microelectronic package having a silicon MEMS microphone;

FIGS. 4c and 4d illustrate subsequent steps of the fourth preferred manufacturing process;

FIGS. 4e and 4f are different views of the package which is obtained as a result of the fourth preferred manufacturing process; and

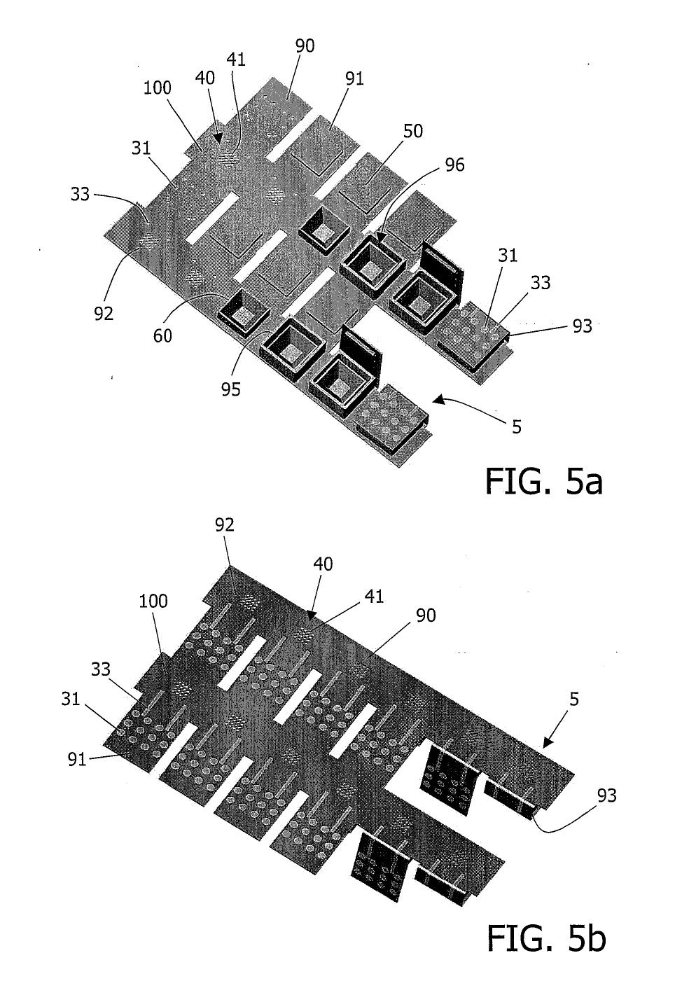

FIGS. 5a and 5b are different views of a basic panel comprising two rows of interconnected substrates, wherein subsequent substrates of a row are in subsequent stages of a fifth preferred process of manufacturing a microelectronic package having a silicon MEMS microphone.

FIGS. 1a, 1b, 1c, 1d, 1e and 1f illustrate subsequent steps of a first preferred process of manufacturing a microelectronic package having a silicon MEMS microphone.

In a first step of the manufacturing process, which is illustrated by FIG. 1a, a sacrificial carrier 20 is provided. On a carrying surface 21 of the sacrificial carrier 20, a pattern 30 of electrically conductive connection pads 31, first electrically conductive tracks 32 connected to the electrically conductive connection pads 31 and relatively short second electrically conductive tracks 33 is arranged. The sacrificial carrier 20 may for example comprise aluminum, and the electrically conductive components 31, 32, 33 may for example comprise copper. Besides the pattern 30, a square layer 40 comprising tiny holes 41 is arranged on the carrying surface 21 of the sacrificial carrier 20. In the following, this square layer 40 will also be indicated as grid 40.

In a second step of the manufacturing process, which is illustrated by FIG. 1b, a rectangular layer 13 of a flexible material is applied to the carrying surface 21 of the sacrificial carrier 20 and a portion of the pattern 30 that is present on the carrying surface 21, in particular a portion of the first electrically conductive tracks 32. The layer 13 may comprise any suitable kind of nonconducting flexible material, for example a polyamide material, an acrylic material, or an epoxy material.

In a third step of the manufacturing process, which is illustrated by FIG. 1c, an IC chip 50 is placed on the sacrificial carrier 20, and is connected to free ends of the first electrically conductive tracks 32 and to free ends of the second electrically conductive tracks 33 in a suitable way, for example by a flip-chip process which is known per se.

In a fourth step of the manufacturing process, which is illustrated by FIG. 1d, a mould tool (not shown) having two cavities and a central rib extending between the cavities is placed on the sacrificial carrier 20, wherein the central rib is placed on the layer 13 of flexible material, so that this layer 13 is completely covered by the central rib. In one of the cavities of the mould tool, a projecting portion is present. When the mould tool is in the right position with respect to the sacrificial carrier 20 and all that is arranged on its carrying surface 21, the grid 40 is completely covered by this projecting portion of the mould tool.

After the mould tool has been put in place with respect to the sacrificial carrier 20 and all that is arranged on its carrying surface 21, an injection molding process is carried out, during which plastic material is introduced in the cavities of the mould tool. Subsequently, the plastic material is allowed to cure, and the mould tool is removed. In the process, at one side of the layer 13 of flexible material, a rectangular first plastic body 11 is formed, which is positioned adjacent to the layer 13 of flexible material, and which is arranged on an area of the sacrificial carrier 20 where the electrically conductive connection pads 31 and portions of the first electrically conductive tracks 32 are present. A central portion 14 of the first plastic body 11 is recessed with respect to a rim 15 of the first plastic body 11. At another side of the layer 13 of flexible material, a rectangular second plastic body 12 is formed, which is positioned adjacent to the layer 13 of flexible material, and which is arranged on an area of the sacrificial carrier 20 where portions of the first electrically conductive tracks 32, the IC chip 50, the second electrically conductive tracks 33 and the grid 40 are present. The IC chip 50 is encapsulated in the plastic material of the second plastic body 12, and free ends of the second electrically conductive tracks 33 and the grid 40 are left free, as the second plastic body 12 comprises a cavity 16 at the position where the projecting portion of the mould tool has been during the injection molding process.

In a fifth step of the manufacturing process, which is illustrated by FIG. 1e, the sacrificial carrier 20 is removed by means of etching.

In a sixth step of the manufacturing process, which is illustrated by FIG. 1f, a silicon MEMS microphone 60 is placed in the cavity 16 of the second plastic body 12, in an upside down orientation, wherein contacts at an upper side of the microphone 60 are connected to the free ends of the second electrically conductive tracks 33.

In a seventh step of the manufacturing process, the whole of the first plastic body 11, the second plastic body 12 and the layer 13 of flexible material extending in between is folded in a way which resembles closing of a book, wherein a package 1 is formed in which the first plastic body 11 and the second plastic body 12 are positioned on top of each other, and wherein the layer 13 of flexible material extends at one side of the package 1. In order to make sure that the plastic bodies 11, 12 remain on top of each other, the plastic bodies 11, 12 are fixed with respect to each other, for example by means of glue.

In FIGS. 1g and 1h, different views of the package 1 are shown. In FIG. 1g, the package 1 is shown with the second plastic body 12 up, whereas in FIG. 1h, the package 1 is shown with the first plastic body 11 up. The package 1 is connectable to another electrical device (not shown) such as a printed circuit board by means of the electrically conductive connection pads 31 which are present on an outside of the package 1. In the process of connecting the package 1 to another electrical device, any suitable technique may be applied, for example soldering.

In the package 1, the microphone 60 is connected to the IC chip 50 through the second electrically conductive tracks 33. When the package 1 is connected to another electrical device, the IC chip 50 is connected to this device through the first electrically conductive tracks 32 and the electrically conductive connection pads 31. During operation of the microphone 60, an electrical signal transmitted by the microphone 60 is received by the IC chip 50 through the second electrically conductive tracks 33, and is processed by the IC chip 50. Output provided by the IC chip 50 is transmitted through the first electrically conductive tracks 32 and the electrically conductive connection pads 31.

It is noted that it is not necessary that all of the electrically conductive connection pads 31 are applied for the transmittal of an electrical signal. In the shown example, one of the electrically conductive connection pads 31 is not connected to the IC chip 50, and is not connected to the microphone 60 either. This electrically conductive connection pad 31 only has a function in the physical connection of the package 1 to another device. Hence, it is not necessary for this connection pad 31 to be electrically conductive.

The grid 40 that is arranged in the second plastic body 12 serves for protecting the interior of the package 1 from the influence of light, dust, water, etc. Still, as the grid 40 comprises the holes 41, sound waves are allowed to reach the microphone 60 arranged right behind the grid 40.

For the purpose of a proper operation of the microphone 60, an acoustical back chamber is needed. In the package 1, the acoustical back chamber is constituted by a hole in a silicon frame of the microphone 60 itself and the space offered by the recessed central portion 14 of the first plastic body 11.

The package 1 is relatively small, and is therefore suitable for application in all kinds of devices, also in portables such as mobile phones. For example, a length of the package 1 may be in an order of 4 mm, a width of the package 1 may be in an order of 2 mm, and a height of the package 1 may be in an order of 1 mm.

FIGS. 2a, 2b, 2c, 2d, 2e and 2f illustrate subsequent steps of a second preferred process of manufacturing a microelectronic package having a silicon MEMS microphone.

The second preferred manufacturing process is almost similar to the first preferred manufacturing process as described in the foregoing. The only difference is that a larger layer of flexible material, which is indicated by reference numeral 13a in FIGS. 2b, 2c, 2d, 2e and 2f, is applied, wherein the layer 13a also covers the areas where the first plastic body 11 and the second plastic body 12 are disposed, with the exception of the areas where the IC chip 50 and the microphone 60 are arranged.

FIG. 2g shows a package 2 which is obtained as a result of the second preferred manufacturing process. The only difference of this package 2 with respect to the package 1 which is obtained as a result of the first preferred manufacturing process is that the layer 13a of flexible material covers a larger portion of an outside of the package 2.

FIGS. 3a and 3b show a substrate 70 which is used in a third preferred process of manufacturing a microelectronic package having a silicon MEMS microphone. The substrate 70 has a rectangular shape and comprises a flexible material. In a first portion 71 of the substrate 70, at a side which is intended to be at an outside of the package to be manufactured, and which is shown in FIG. 3a, a number of electrically conductive connection pads 31 is arranged. In the shown example, the number is sixteen, but it is just as well possible to have another number of electrically conductive connection pads 31. Furthermore, two electrically conductive tracks 33 are arranged on the substrate 70, which extend from two of the electrically conductive connection pads 31 on the first portion 71 of the substrate 70 to a second portion 72 of the substrate 70.

In FIG. 3b, a side of the substrate 70 which is intended to be at an inside of the package to be manufactured is shown. In this Figure, it can be seen that an outer ring of the electrically conductive connection pads 31 is accessible from this side of the substrate 70. The same applies to small portions of free ends of the electrically conductive tracks 33.

Besides the electrically conductive connection pads 31 and the electrically conductive tracks 33, the substrate 70 comprises a grid 40 having tiny holes 41.

During the manufacturing process, a number of elements is arranged on the substrate 70, at the side which is intended to be at the inside of the package to be manufactured. The obtained whole of the substrate 70 and the elements is shown in FIGS. 3c and 3d. In particular, a first ring-shaped element 55 is arranged on the first portion 71 of the substrate 70, and a second ring-shaped element 65 is arranged on the second portion 72 of the substrate 70, wherein an intermediate portion 73 of the substrate 70 is left free. In the process, the ring-shaped elements 55, 65 are attached to the substrate 70 in any suitable manner, preferably by glueing.

Furthermore, inside a space 56 enclosed by the first ring-shaped element 55, an IC chip 50 is arranged on the substrate 70, wherein contacts of the IC chip 50 are connected to a number of the electrically conductive connection pads 31, including the connection pads 31 which are in contact with the electrically conductive tracks 33. In the shown example, the connection between the contacts of the IC chip 50 and the electrically conductive connection pads 31 is established through connection wires 51, but that does not alter the fact that the IC chip 50 may also be connected to the electrically conductive connection pads 31 in another suitable manner, for example by a flip-chip process.

Inside a space 66 enclosed by the second ring-shaped element 65, a silicon MEMS microphone 60 is arranged on the substrate 70, in an upside down orientation, wherein contacts at an upper side of the microphone 60 are connected to the accessible portions of the free ends of the electrically conductive tracks 33. In this way, a connection between the microphone 60 and the IC chip 50 is realized.

After the ring-shaped elements 55, 65, the IC chip 50 and the microphone 60 have been arranged on the substrate 70, and all connections as described in the foregoing have been established, a package is formed by folding the substrate 70 in three, wherein the ring-shaped elements 55, 65 are put on top of each other, while the IC chip 50 and the substrate 60 are enclosed inside the package. After folding of the substrate 70 has taken place, the ring-shaped elements 55, 65 are attached to each other by means of glue or other suitable fixing means. The package 3 which is obtained as a result of third preferred manufacturing process is shown in FIG. 3e.

The ring-shaped elements 55, 65 may be formed in any suitable way, for example by folding a strip. The ring-shaped elements 55, 65 may be completely closed, but may also comprise a small opening, in conformity with that which is shown in FIG. 3c. A thickness of the ring-shaped elements 55, 65 may be in an order of 150 μm. Suitable materials in respect of the ring-shaped elements 55, 65 are iron, iron alloys, copper, copper alloys, brass, phosphor bronze, etc.

In the packages 1, 2 which are obtained as a result of the first preferred manufacturing process and the second preferred manufacturing process, the IC chip 50 and the microphone 60 are arranged next to each other, in the same plastic body 12. However, in the package 3 which is obtained as a result of the third manufacturing process, the IC chip 50 and the microphone 60 are arranged above each other, on different portions 71, 72 of the substrate 70. Consequently, a length of the latter package 3 may be smaller. In this package 3, the acoustical back chamber of the microphone 60 is constituted by a hole in a silicon frame of the microphone 60 itself and a portion of the space 56 enclosed by the first ring-shaped element 55, i.e. space which is not occupied by the IC chip 50.

FIGS. 4a and 4b show a substrate 80 which is used in a fourth preferred process of manufacturing a microelectronic package having a silicon MEMS microphone. The substrate 80 has a rectangular shape and comprises a flexible material. In a first portion 81 of the substrate 80, at a side which is intended to be at an outside of the package to be manufactured, and which is shown in FIG. 4a, a number of electrically conductive connection pads 31 is arranged. In the shown example, the number is twelve, but it is just as well possible to have another number of electrically conductive connection pads 31. Furthermore, first electrically conductive tracks 32 are arranged on the substrate 80, which extend from four of the electrically conductive connection pads 31 on the first portion 81 of the substrate 80 to a second portion 82 of the substrate 80. Also, on the second portion 82 of the substrate 80, two relatively short electrically conductive tracks 33 are arranged, which are referred to as second electrically conductive tracks 33.

In FIG. 4b, a side of the substrate 80 which is intended to be at an inside of the package to be manufactured is shown. In this Figure, it can be seen that free ends of both the first electrically conductive tracks 32 and the second electrically conductive tracks 33 are accessible from this side of the substrate 80.

Besides the electrically conductive connection pads 31 and the electrically conductive tracks 32, 33, the substrate 80 comprises a grid 40 having tiny holes 41.

During the manufacturing process, a number of elements is arranged on the substrate 80, at the side which is intended to be at the inside of the package to be manufactured, in two steps. In a first step, which is illustrated by FIG. 4c, an IC chip 50 is arranged on the second portion 82 of the substrate 80, and a silicon MEMS microphone 60 is arranged on the second portion 82 of the substrate 80 as well, in an upside down orientation. In the process, contacts of the IC chip 50 are connected to the free ends of the first electrically conductive tracks 32 and to one set of free ends of the second electrically conductive tracks 33, and contacts at an upper side of the microphone 60 are connected to another set of free ends of the second electrically conductive tracks 33. In this way, it is achieved that the IC chip 50 is connected to four electrically conductive connection pads 31, via the first electrically conductive tracks 32, and that the microphone 60 is connected to the IC chip 50, via the second electrically conductive tracks 33.

After the IC chip 50 and the microphone 60 have been arranged on the substrate 80, and all connections as described in the foregoing have been established, a cover 85 is provided and arranged on the second portion 82 of the substrate 80, wherein both the IC chip 50 and the microphone 60 are enclosed in a space 86 delimited by the cover 85 and the second portion 82 of the substrate 80. Preferably, the cover is attached to the second portion 82 of the substrate 80 by glueing.

The step of providing the cover 85 is illustrated by FIG. 4d. A thickness of walls of the cover 85 may be in an order of 100 μm. Suitable materials in respect of the cover 85 are iron alloys, copper alloys, phosphor bronze, etc. Preferably, the cover 85 is formed by means of deep drawing techniques.

In a last step of the fourth preferred manufacturing process, the substrate 80 is folded in three, along the cover 85, and the first portion 81 of the substrate 80 is attached to the cover 85. In this way, a package 4 is obtained, which is shown in FIGS. 4e and 4f. In this package 4, a height of the cover 85 is bridged by an intermediate portion 83 of the substrate 80, extending between the first portion 81 and the second portion 82. Furthermore, in this package 4, the IC chip 50 and the microphone 60 are arranged next to each other, on the same portion 82 of the substrate 80. The acoustical back chamber of the microphone 60 is constituted by a hole in a silicon frame of the microphone 60 itself and free space that is present inside the cover 85.

FIGS. 5a and 5b show a basic panel 100 comprising two rows of interconnected substrates 90, which is suitable to be used in a fifth preferred process of manufacturing a microelectronic package having a silicon MEMS microphone. By applying a basic panel 100 as shown, it is possible to manufacture more than one package at a time. In a practical way of carrying out the fifth preferred manufacturing process, the basic panel 100 is positioned in a device having subsequent tools for performing subsequent steps of the manufacturing process, wherein the basic panel 100 is moved stepwise with respect to these tools. Eventually, when a package is ready, the package is cut off of the basic panel 100. In the shown example, the basic panel 100 comprises two rows of substrates 90, so that two packages at a time are obtained. Within the scope of the present invention, the number of rows of substrates 90 may be chosen freely.

The basic panel 100 comprises a flexible material. Each substrate 90 has a rectangular shape. In a first portion 91 of the substrate 90, at a side which is intended to be at an outside of the package to be manufactured, and which is shown in FIG. 5b, a number of electrically conductive connection pads 31 is arranged. In the shown example, the number is twelve, but it is just as well possible to have another number of electrically conductive connection pads 31. Furthermore, two electrically conductive tracks 33 are arranged on the substrate 90, which extend from the first portion 91 of the substrate 90 to a second portion 92 of the substrate 90.

In FIG. 5a, a side of the substrates 90 which is intended to be at an inside of the package to be manufactured is shown. In this Figure, it can be seen that a number of the electrically conductive connection pads 31 is accessible from this side of the substrates 90. The same applies to small portions of free ends of the electrically conductive tracks 33.

Besides the electrically conductive connection pads 31 and the electrically conductive tracks 33, the substrates 90 comprise a grid 40 having tiny holes 41.

In the following, subsequent steps of the fifth preferred manufacturing process are described.

In a first step, an IC chip 50 is arranged on the first portion 92 of the substrate 90, at the side which is intended to be at the inside of the package to be manufactured, wherein contacts of the IC chip 50 are connected to at least a few of the accessible electrically conductive connection pads 31.

In a second step, a silicon MEMS microphone 60 is arranged on the second portion 92 of the substrate 90, in an upside down orientation, wherein contacts at an upper side of the microphone 60 are connected to the accessible portions of the free ends of the electrically conductive tracks 33, which are present in the second portion 92 of the substrate 90.

In a third step, a ring-shaped element 95 is arranged on the second portion 92 of the substrate 90, around the microphone 60, so that the microphone 60 is positioned in a space 96 enclosed by the ring-shaped element 95. Preferably, the ring-shaped element 95 is glued to the second portion 92 of the substrate 90. It is noted that the ring-shaped element 92 is higher than the microphone 60. The ring-shaped element 95 may be formed in any suitable way, for example by folding a strip. The ring-shaped element 95 may be completely closed, in conformity with that which is shown in FIG. 5a, but may also comprise a small opening. A thickness of the ring-shaped element 95 may be in an order of 150 μm. Suitable materials in respect of the ring-shaped element 95 are iron, iron alloys, copper, copper alloys, etc. For example, the ring-shaped element 95 may comprise tin plate or gilt brass.

In a fourth step, the substrate 90 is folded in three, along the ring-shaped element 95, wherein an open side of the ring-shaped element 95 is closed by the first portion 91 of the substrate 90, and wherein the first portion 91 of the substrate 90 is attached to the ring-shaped element 95. In the process, the IC chip 50 arranged on the first portion 91 of the substrate 90 ends up inside the ring-shaped element 95. Providing one ring-shaped element 95 which is at least as high as both the IC chip 50 and the microphone 60 together is a feasible alternative to providing two ring-shaped elements 55, 65, wherein each of the IC chip 50 and the microphone 60 is enclosed by one of the ring-shaped elements 55, 65, and wherein the ring-shaped elements 55, 65 are eventually put on top of each other, as is the case in the third preferred manufacturing process.

In a fifth step, the obtained package 5 is separated from the basic panel 100, for example by means of cutting. In this package 5, a height of the ring-shaped element 95 is bridged by an intermediate portion 93 of the substrate 90, extending between the first portion 91 and the second portion 92. Furthermore, in this package 5, the IC chip 50 and the microphone 60 are arranged above each other, on different portions 91, 92 of the substrate 90. The acoustical back chamber of the microphone 60 is constituted by a hole in a silicon frame of the microphone 60 itself and free space that is present inside the ring-shaped element 95.

In short, the fifth preferred process of manufacturing a microelectronic package 5 comprising a silicon MEMS microphone 60 comprises the following steps: providing a basic panel 100 having several rows of interconnected substrates 90, wherein the substrates 90 are provided with electrically conductive connection pads 31, electrically conductive tracks 33, and a grid 40 comprising tiny holes 41; arranging an IC chip 50, a silicon MEMS microphone 60 and a ring-shaped element 95 on the substrates 90, wherein the ring-shaped element 95 is arranged around the microphone 60; and folding the substrates 90 in three, wherein an open side of the ring-shaped element 95 is closed. The IC chip 50 and the microphone 60 are safely accommodated in the package 5 that is obtained in this way. The connection pads 31 allow for easy connection of the package 5 to another device, while electrical connections to the IC chip 50 are also easily realized through these connection pads 31. An electrical connection of the microphone 60 to the IC chip 50 is realized through the electrically conductive tracks 33.

The packages 1, 2, 3, 4, 5 shown in the Figures and described in the foregoing are only a few of the numerous possibilities existing within the scope of the present invention.

According to the present invention, by subsequently preparing a package in an elongated, open form and performing a folding step, a compact and robust package 1, 2, 3, 4, 5 is obtained. The manufacturing process of the packages 1, 2, 3, 4, 5 does not involve any complicated steps, and may be performed at low cost. Also, the applied materials of the package do not need to be expensive.

The package 1, 2, 3, 4, 5 according to the present invention is as small as possible, and does not comprise unnecessary space. Moreover, the space needed for an acoustical back chamber of the microphone 60 is kept as small as possible, wherein a hole in a silicon frame of the microphone 60 itself is also applied as a portion of this acoustical back chamber.

Furthermore, the package 1, 2, 3, 4, 5 according to the present invention is easily connectable to a supporting structure by means of connection pads 31. Also, through the connection pads 31, which are electrically conductive, it is possible to establish electrical connections to the IC chip 50 and the microphone 60 in a most convenient manner.

In the package 1, 2, 3, 4, 5 according to the present invention, a membrane of the microphone 60, which is deformed under the influence of sound, is positioned right behind the grid 40. In this way, an optimal receipt of sound is guaranteed.

In the shown examples, the packages 1, 2, 3, 4, 5 comprise a silicon MEMS microphone 60. However, that does not alter the fact that within the scope of the present invention, another acoustical transducer may be applied instead. Furthermore, all of the shown packages 1, 2, 3, 4, 5 comprise one IC chip 50 and one microphone 60. It is noted that the IC chip 50 is not an essential element of the package 1, 2, 3, 4, 5, although it is preferred to have an IC chip 50 in close proximity of the microphone 60. In such a case, electrically conductive tracks should be provided for connecting the microphone 60 to the electrically conductive connection pads 31. On the other hand, it is possible that the package 1, 2, 3, 4, 5 is equipped with more microelectronic elements.

It will be clear to a person skilled in the art that the scope of the present invention is not limited to the examples discussed in the foregoing, but that several amendments and modifications thereof are possible without deviating from the scope of the present invention as defined in the attached claims.

1. Method of manufacturing a microelectronic package (1, 2, 3, 4, 5) comprising an acoustical transducer such as a silicon MEMS microphone (60), comprising the following steps:
providing a basic structure having three portions, namely a first package portion (11; 71, 55; 81; 91) having electrically conductive connection pads (31) for connection of the package (1, 2, 3, 4, 5) to another electrical device, a second package portion (12; 72, 65; 82, 85; 92, 95) having a space (16, 66, 86, 96) in which the acoustical transducer (60) is accommodated, an intermediate package portion (13, 73, 83, 93) which is arranged between the first package portion (11; 71, 55; 81; 91) and the second package portion (12; 72, 65; 82, 85; 92, 95), and having electrically conductive tracks (32,33) extending from the electrically conductive connection pads (31) on the first package portion (11; 71, 55; 81; 91) to the second package portion (12; 72, 65; 82, 85; 92, 95), via the intermediate pac portion (13, 73, 83, 93) and wherein the acoustical transducer (60) is connected to ends of the electrically conductive tracks (32,33);
folding the basic structure, wherein a package (1, 2, 3, 4, 5) is formed in which the first package portion (11; 71, 55; 81; 91) and the second package portion (12; 72, 65; 82, 85; 92, 95) are positioned on top of each other, and in which the electrically conductive connection pads (31) of the first package portion (11; 71, 55; 81; 91) are positioned at an outside of the package (1, 2, 3, 4, 5), while the acoustical transducer (60) is positioned inside the package (1, 2, 3, 4, 5); and
fixing the first package portion (11; 71, 55; 81; 91) and the second package portion (12; 72, 65; 82, 85; 92, 95) with respect to each other.

2. Method according to claim 1, wherein the step of providing the basic structure comprises the steps of providing a foldable substrate (70, 80, 90); arranging the electrically conductive connection pads (31) for connection of the package (3, 4, 5) to another electrical device on a first portion (71, 81, 91) of the substrate (70, 80, 90); and arranging the acoustical transducer (60) on a second portion (72, 82, 92) of the substrate (70, 80, 90); and wherein the step of folding the basic structure comprises folding the substrate (70, 80, 90) in three.

3. Method according to claim 1, comprising the step of providing the second package portion with a layer (12) having a cavity (16) for receiving the acoustical transducer (60).

4. Method according to claim 1, comprising the step of providing the second package portion with a ring-shaped element (65, 95) enclosing a space (66, 96) for receiving the acoustical transducer (60).

5. Method according to claim 1, comprising the step of providing the second package portion with a cover (85) having a space (86) for accommodating the acoustical transducer (60), wherein the cover (85) is placed over the acoustical transducer (60) after the transducer (60) has been arranged on the second package portion.

6. Method according to claim 1, wherein another microelectronic element such as an IC chip (50) is provided, wherein this element (50) is arranged on the first package portion (71, 55; 91), and wherein this element (50) and the acoustical transducer (60) are positioned above each other after the step of folding the basic structure has been carried out.

7. Method according to claim 6, comprising the step of providing the first package portion with a ring-shaped element (55) enclosing a space (56) for receiving the microelectronic element (50).

8. Method according to claim 1, wherein the basic structure is initially part of a larger basic panel (100), and wherein the basic structure is completely separated from the basic panel (100) after the steps of folding the basic structure and fixing the first package portion (91) and the second package portion (92, 95) with respect to each other have been carried out.

9. Foldable basic structure for use in a method according to claim 1, comprising a first package portion (11; 71, 55; 81; 91) having electrically conductive connection pads (31), a second package portion (12; 72, 65; 82, 85; 92, 95) having a space (16, 66, 86, 96) in which an acoustical transducer (60) is accommodated, and an intermediate package portion (13, 73, 83, 93) which is arranged between the first package portion (11; 71, 55; 81; 91) and the second package portion (12; 72, 65; 82, 85; 92, 95), and having electrically conductive tracks (32,33) extending from the electrically conductive connection pads (31) on the first package portion (11; 71, 55; 81; 91) to the second package portion (12; 72, 65; 82, 85; 92, 95), via the intermediate package portion (13, 73, 83, 93) and wherein the acoustical transducer (60) is connected to ends of the electrically conductive tracks (32,33).

10. Foldable basic structure according to claim 9, further comprising another microelectronic element such as an IC chip (50) and electrically conductive tracks (33) extending from this element (50) to the acoustical transducer (60).

11. Package (1, 2, 3, 4, 5), comprising:
an acoustical transducer such as a silicon MEMS microphone (60);
a first package portion (11; 71, 55; 81; 91) having first electrically conductive connection pads (31) for connection of the package (1, 2, 3, 4, 5) to another electrical device;
a second package portion (12; 72, 65; 82, 85; 92, 95) having a space (16, 66, 86, 96) in which the acoustical transducer (60) is accommodated, wherein the package portions are positioned on top of each other;
an intermediate sheet (13, 73, 83, 93) which is connected to both package portions, and which is arranged at an outside of the package (1, 2, 3, 4, 5); and
electrically conductive tracks (32,33) extending from the electrically conductive connection pads (31) on the first package portion (11; 71, 55; 81; 91) to the second package portion (12; 72, 65; 82, 85; 92, 95), via the intermediate package portion (13, 73, 83, 93) and wherein the acoustical transducer (60) is connected to ends of the electrically conductive tracks (32,33).

12. Package (3, 4, 5) according to claim 11, wherein the intermediate sheet (73, 83, 93) is a middle part of a substrate (70, 80, 90) folded in three, which extends at an outside of the package (3, 4, 5), and which is part of both the first package portion (71, 55; 81; 91) and the second package portion (72, 65; 82, 85; 92, 95).

13. Package (1, 2) according to claim 11, wherein the second package portion comprises a layer (12) in which a cavity (16) is arranged, and wherein the acoustical transducer (60) is positioned in the cavity (16).

14. Package (3, 5) according to claim 11, wherein the second package portion comprises a ring-shaped element (65, 95), and wherein the acoustical transducer (60) is positioned in a space (66, 96) enclosed by the element (65, 95).

15. Package (4) according to claim 11, wherein the second package portion comprises a cover (85), and wherein the acoustical transducer (60) is positioned in a space (86) enclosed by the cover (85).

16. Package (3, 5) according to claim 11, further comprising another microelectronic element such as an IC chip (50) and electrically conductive tracks (33) extending from this element (50) to the acoustical transducer (60), wherein the microelectronic element (50) is arranged on the first package portion (71, 55; 91), wherein the microelectronic element (50) and the acoustical transducer (60) are positioned above each other, and wherein the electrically conductive tracks (33) extending from the microelectronic element (50) to the acoustical transducer (60) extend at the outside of the package (3, 5), over the intermediate sheet (73, 93).

17. Package (3) according to claim 16, wherein the first package portion comprises a ring-shaped element (55), and wherein the microelectronic element (50) is positioned in a space (56) enclosed by the element (55).
